(19) United States
(12) Patent Application Publication
(10) Pub. No.: US 2025/0321286 A1
(43) Pub. Date: Oct. 16, 2025

(54) CONTROL METHOD, CONTROL DEVICE, ENERGY STORAGE POWER SUPPLY, AND STORAGE MEDIUM

(71) Applicant: SHENZHEN HELLO TECH ENERGY CO., LTD, Shenzhen (CN)

(72) Inventors: Jichang WU, Shenzhen (CN); Wenqun LI, Shenzhen (CN); Xinxin AN, Shenzhen (CN); Qian ZHOU, Shenzhen (CN); Gaosong SHEN, Shenzhen (CN); Zhongwei SUN, Shenzhen (CN)

(21) Appl. No.: 19/250,119

(22) Filed: Jun. 26, 2025

Related U.S. Application Data
(63) Continuation of application No. PCT/CN2025/091317, filed on Apr. 25, 2025.

(30) Foreign Application Priority Data
Aug. 29, 2024 (CN) 202411218498.9

(51) Int. Cl. G01R 31/388; G01R 31/367; H01M 10/42; H02J 7/00

(52) U.S. Cl. CPC G01R 31/388; G01R 31/367; H01M 10/425; H02J 7/00712; H01M 2010/4271

(57) ABSTRACT

Provided are a control method, a control device, an energy storage power supply, and a storage medium. The control method includes: obtaining a load current and a load duration of the energy storage power supply when the energy storage power supply is disconnected from a charger and is under load; obtaining a correction duration of the energy storage power supply; obtaining a deviation SOC of the energy storage power supply; determining a speed factor based on a ratio of the deviation SOC to the correction duration; and obtaining the first state of charge of the energy storage power supply based on the load current, the speed factor, and the load duration until the load duration reaches the correction duration.

### CROSS-REFERENCE TO RELATED APPLICATION

This application is a continuation of International Application No. PCT/CN2025/091317, filed on Apr. 25, 2025, which claims priority to and benefits of Chinese patent application No. 202411218498.9, filed with China National Intellectual Property Administration on Aug. 29, 2024, the entire contents of which are incorporated herein by reference.

### FIELD

The present disclosure relates to the technical field of energy storage power supplies, and more particularly, to a control method, a control device, an energy storage power supply, and a storage medium.

### BACKGROUND

In the conventional technology, when a fully charged energy storage power supply remains connected to a charging gun, it enters a sleep (standby) state. Due to limited collection accuracy, a battery management system (BMS) of the energy storage power supply does not collect the consumption of the energy storage power supply, resulting in deviations in the accuracy of a monitored state of charge (SOC). The inventor has realized that when the energy storage power supply is fully charged for a period of time, if the charging gun is unplugged, and the energy storage power supply is used under load, a displayed SOC of the energy storage power supply does not match an actual SOC, resulting in a sudden change in the displayed SOC during the use of the energy storage power supply.

### SUMMARY

Embodiments of the present disclosure provide a control method, a control device, an energy storage power supply, and a storage medium to solve at least one of the above technical problems.

A control method according to the embodiments of the present disclosure is applied to an energy storage power supply that displays a first SOC. The method includes: obtaining a load current and a load duration of the energy storage power supply when the energy storage power supply is disconnected from a charger and is under load; obtaining a correction duration of the energy storage power supply; obtaining a deviation SOC of the energy storage power supply; determining a speed factor based on a ratio of the deviation SOC to the correction duration; and obtaining the first SOC of the energy storage power supply based on the load current, the speed factor, and the load duration until the load duration reaches the correction duration.

In the above control method, the first SOC of the energy storage power supply may be obtained based on the load current, the speed factor, and the load duration, improving accuracy of the first SOC. In this way, sudden jumps in the first SOC during use of the energy storage power supply are avoided to a certain extent.

A control device according to the embodiments of the present disclosure includes: a processor; and a memory having a computer program stored thereon. The computer program, when executed by the processor, implements steps of the control method according to the above embodiments.

An energy storage power supply according to the embodiments of the present disclosure includes the above control device.

The embodiments of the present disclosure provide a computer-readable storage medium having a computer program stored thereon. The computer program, when executed by a processor, implements steps of the control method according to the above embodiments.

Additional aspects and advantages of the present disclosure will be provided at least in part in the following description, or will become apparent at least in part from the following description, or can be learned from practicing of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 to FIG. 9 each is a schematic flowchart of a control method according to embodiments of the present disclosure.

FIG. 10 is a schematic diagram of modules of an energy storage power supply according to an embodiment of the present disclosure.

### DESCRIPTION OF MAIN ELEMENT SYMBOLS

Energy storage power supply 1, control device 2, memory 21, processor 22, battery module 3.

### DETAILED DESCRIPTION OF THE EMBODIMENTS

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limit, the embodiments of the present disclosure.

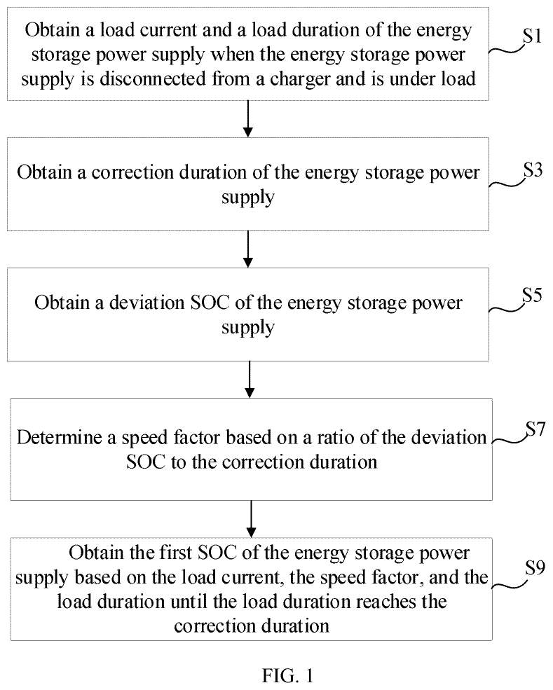

As illustrated in FIG. 1, a control method according to an embodiment of the present disclosure is applied to an energy storage power supply 1 that displays a first SOC. The method includes following steps S1 to S9.

At step S1, a load current and a load duration of the energy storage power supply 1 are obtained when the energy storage power supply 1 is disconnected from a charger and is under load.

At step S3, a correction duration of the energy storage power supply 1 is obtained.

At step S5, a deviation SOC of the energy storage power supply 1 is obtained.

At step S7, a speed factor is determined based on a ratio of the deviation SOC to the correction duration.

At step S9, a first SOC of the energy storage power supply 1 is obtained based on the load current, the speed factor, and the load duration until the load duration reaches the correction duration.

In an embodiment, the load current refers to a magnitude of a current supplied by the energy storage power supply 1 when the energy storage power supply 1 supplies power to an external load, that is, an actual current magnitude when the energy storage power supply 1 supplies electric energy to the load. The load current may be monitored in real time by a BMS of the energy storage power supply 1, and changes with a change of the load. In an embodiment, the load may include, but is not limited to, a household appliance (such as an oven, an induction cooker, a baking pan, a television, and a refrigerator), a mobile device (such as a smart phone, a tablet computer, a laptop, and a camera or video camera).

The load duration refers to a duration during which the energy storage power supply 1 operates at the load current.

The correction duration refers to a time period determined based on the load current and used to correct the first SOC. In an embodiment, the correction duration may be greater than or equal to 2 minutes (min) and less than or equal to 8 minutes.

The first SOC may be an SOC displayed on a user interface of the energy storage power supply 1, and is used to remind the user of the remaining power of the energy storage power supply 1 and to influence the user's usage decisions.

In an embodiment, the energy storage power supply 1 includes a battery module 3 and one or more electronic components (for example, a BMS, an inverter, and the like). When the energy storage power supply 1 remains connected to the charger after being fully charged, the energy storage power supply 1 enters a sleep state. In this state, the electronic components inside the energy storage power supply 1 consume battery power at a predetermined static self-consumption power level. However, the BMS has limited collection accuracy, and is unable to monitor tiny self-consumption currents (of a milliampere or microampere level, for example) in real time. When the energy storage power supply 1 suddenly enters a load stage from the sleep stage, the BMS cannot accurately reflect the actual SOC, which may lead to inaccurate accuracy of the first SOC, causing a sudden jump in the first SOC. This phenomenon is particularly prominent in low-temperature environments. In the low-temperature environments, a voltage of the battery module 3 drops rapidly, which causes the SOC to change faster, increasing probability of the sudden jump in the first SOC. In addition, when the power of the battery module 3 is close to a low level, the voltage drop of the battery module 3 tends to become steeper, further increasing the probability of the sudden jump in the first SOC. When the first SOC is displayed on the user interface, the sudden jump in the first SOC affects a user's judgment of battery life of the energy storage power supply 1, reducing user experience.

Therefore, when the energy storage power supply 1 is in a fully charged sleep state, is suddenly disconnected from the charger and is loaded, the first SOC of the energy storage power supply 1 is obtained based on the load current, the speed factor, and the load duration in the loaded stage. That is, SOC deviation caused by capacity loss due to sleep self-consumption power is corrected within the correction duration, in such a manner that problems such as high costs and low integration degree caused by high collection accuracy requirements can be avoided to a certain extent and accuracy of the first SOC can be improved, avoiding a risk of the sudden jump in the first SOC to a certain extent. In this way, effective display of a real-time usage state of the energy storage power supply 1 is ensured, guaranteeing the user experience.

In summary, in the above control method, the first SOC of the energy storage power supply 1 can be obtained based on the load current, the speed factor, and the load duration, improving the accuracy of the first SOC and avoiding occurrence of the sudden jump in the first SOC during use of the energy storage power supply 1.

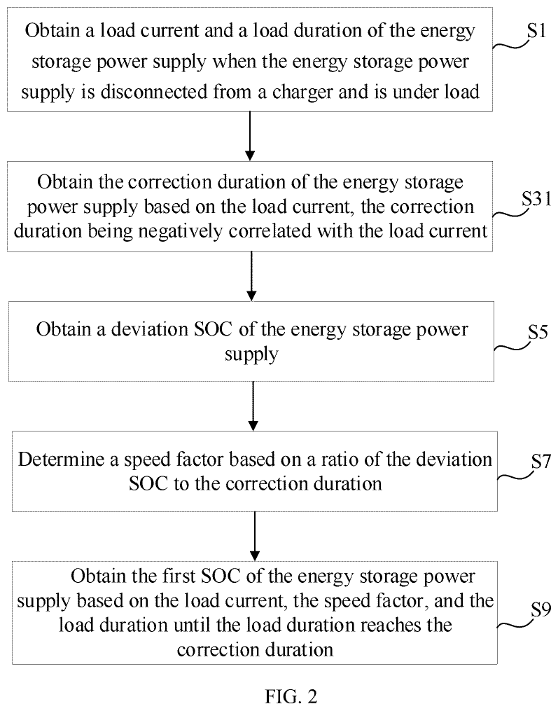

Further, as illustrated in FIG. 2, in some embodiments, step S3 includes following step S31.

At step S31, the correction duration of the energy storage power supply 1 is obtained based on the load current. The correction duration is negatively correlated with the load current.

In an embodiment, a time-current mapping relationship reflects a relationship between the load current and the correction duration. The load current is negatively correlated with the correction duration. The correction duration decreases as the load current increases, and the correction duration increases as the load current decreases.

In the above embodiments, the correction duration may be determined based on the time-current mapping relationship and the load current, ensuring that first SOC of the energy storage power supply 1 can change stably and promptly under different load current conditions. Under a small load current, the energy storage power supply 1 discharges slowly and SOC change is small, a longer correction duration can ensure smooth changes in the first SOC when the first SOC is corrected, improving the user experience. Under a large load current, the energy storage power supply 1 discharges rapidly, and the SOC change is large, a shorter correction duration can quickly correct the first SOC, such that a real SOC can be reflected in a timely and accurate manner.

In an embodiment, there is a predetermined mapping relationship between the correction duration and the load current. In this way, the correction duration may be quickly determined based on the load current and the above predetermined mapping relationship. The mapping relationship may be rated in advance and stored in the BMS, or stored in other components of the energy storage power supply 1, or stored in a terminal device communicatively connected to the energy storage power supply 1. The terminal device includes but is not limited to a mobile phone, a tablet computer, a wearable smart device (a smart helmet, smart glasses, a smart watch, a smart bracelet, etc.), a personal computer, a server, and the like.

Further, in some embodiments, the battery module 3 of the energy storage power supply 1 includes a plurality of cells, and the mapping relationship is related to a rated capacity of the energy storage power supply 1.

A rated capacity (C₀) of the energy storage power supply 1 refers to a total capacity measured under specified conditions for all cells when leaving the factory or after standardized testing. It is the maximum power that all cells can store when fully charged. A unit of the rated capacity may be ampere-hour (A·h).

A discharge rate C is a ratio of the load current to the rated capacity C₀, and indicates how many times the rated capacity C₀ is discharged per hour, that is, a discharge rate. For example, when the rated capacity C₀=10 A·h and the load current is 2 amperes, the discharge rate is 0.2 C, which indicates that all cells are discharged at 0.2 times C₀ per hour, which can last for 5 hours.

In some examples, the mapping relationship is configured as follows. When the discharge rate is less than 0.5 C, that is, when the load current is less than 0.5 times C₀, the correction duration is 8 min (minuets). When the discharge rate is greater than or equal to 0.5 C and less than or equal to 1 C, that is, when the load current is greater than or equal to 0.5 times C₀ and less than or equal to 1 times C₀, the correction duration is 4 minutes. When the discharge rate is greater than 1 C, that is, when the load current is greater than 1 times C₀, the correction duration is 2 minutes. Details are illustrated in Table 1.

TABLE 1
Relationship between correction duration t and load current I

| I(1.0 C = 1*C₀) | t (unit: min) |
|---|---|
| I < 0.5 C | 8 |
| 0.5 C ≤ I ≤ 1.0 C | 4 |
| I > 1.0 C | 2 |

In an example, the rated capacity C₀ of the energy storage power supply 1 is 20 A·h. When the load current is less than 0.5 times C₀, that is, when the load current is less than 10 A (ampere), the correction duration is 8 minutes. When the load current is greater than or equal to 0.5 times C₀ and less than or equal to 1 times C₀, that is, when the load current is greater than or equal to 10 A and less than or equal to 20 A, the correction duration is 4 minutes. When the load current is greater than 1 times C₀, that is, when the load current is greater than 20 A, the correction duration is 2 minutes.

In the above embodiments, the mapping relationship may be determined based on rated capacity C₀ to adapt to energy storage power supplies 1 of different specifications. Therefore, the correction duration is reasonably configured to improve the accuracy of the first SOC.

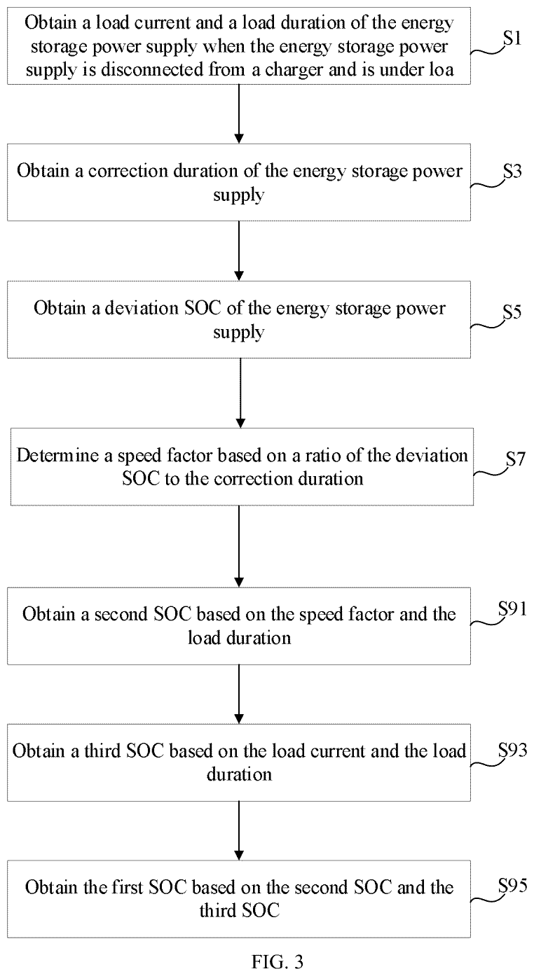

Further, as illustrated in FIG. 3, in some embodiments, step S9 includes following steps S91 to S95.

At step S91, a second SOC is obtained based on the speed factor and the load duration.

At step S93, a third SOC is obtained based on the load current and the load duration.

At step S95, the first SOC is obtained based on the second SOC and the third SOC.

In an embodiment, the speed factor is a ratio of the deviation SOC to the correction duration, and represents the correction speed per unit time during a process of correcting the first SOC. In an embodiment, the speed factor β may be obtained through the following equation:

$$β = S O C ( x \% ) / t ,$$

where, SOC (x %) represents the deviation SOC, and t represents the correction duration.

The second SOC is a product of the load duration and the speed factor, and represents a corrected SOC that changes with the load duration. When the load duration is equal to the correction duration, the corrected SOC is equal to the deviation SOC. At this time, correction of the first SOC is completed. For example, the deviation SOC is 10%, the correction duration is 8 minutes, the second SOC is 2.5% when the energy storage power supply 1 is loaded for 2 minutes, the second SOC is 5% when the energy storage power supply 1 is loaded for 4 minutes, and the second SOC is 10% when the energy storage power supply 1 is loaded for 8 minutes.

It should be understood that, after the correction of the first SOC is completed, the energy storage power supply 1 performs normal SOC calculation and management based on the corrected first SOC.

The third SOC is a ratio of a product of the load duration and load current to the rated capacity C₀ of the energy storage power supply 1, and represents the SOC corresponding to the power consumed by the load current when the energy storage power supply 1 is used under load after the charger is unplugged.

The first SOC is equal to 100% minus the second SOC and the third SOC. In an embodiment, the first SOC may be obtained by the following formula:

$$First S O C = 100 \% - I * {t}_{n} / {C}_{0} - β * {t}_{n} ,$$

where, I represents the load current, tₙ represents the load duration, C0 represents the rated capacity of the energy storage power supply 1, and β represents the speed factor.

In an example, the rated capacity C₀ of the energy storage power supply 1 is 10 A·h, the deviation SOC is 5%, and the load current is 10 A, so the correction duration is 4 minutes. When the energy storage power supply 1 is loaded for 1 minute, the second SOC is 1.25%, the third SOC is 1%, and the first SOC is 97.75%. When the energy storage power supply 1 is loaded for 2 minutes, the second SOC is 2.5%, the third SOC is 2%, and the first SOC is 95.5%. When the energy storage power supply 1 is loaded for 3 minutes, the second SOC is 3.75%, the third SOC is 3%, and the first SOC is 93.25%. When the energy storage power supply 1 is loaded for 4 minutes, the second SOC is 5%, the third SOC is 4%, and the first SOC is 91%. In this case, the correction of the first SOC is completed.

In the above embodiments, the speed factor can ensure that the correction of the first SOC is completed within the correction duration, and also ensure that the first SOC changes smoothly during the process of correcting the first SOC, improving the user experience.

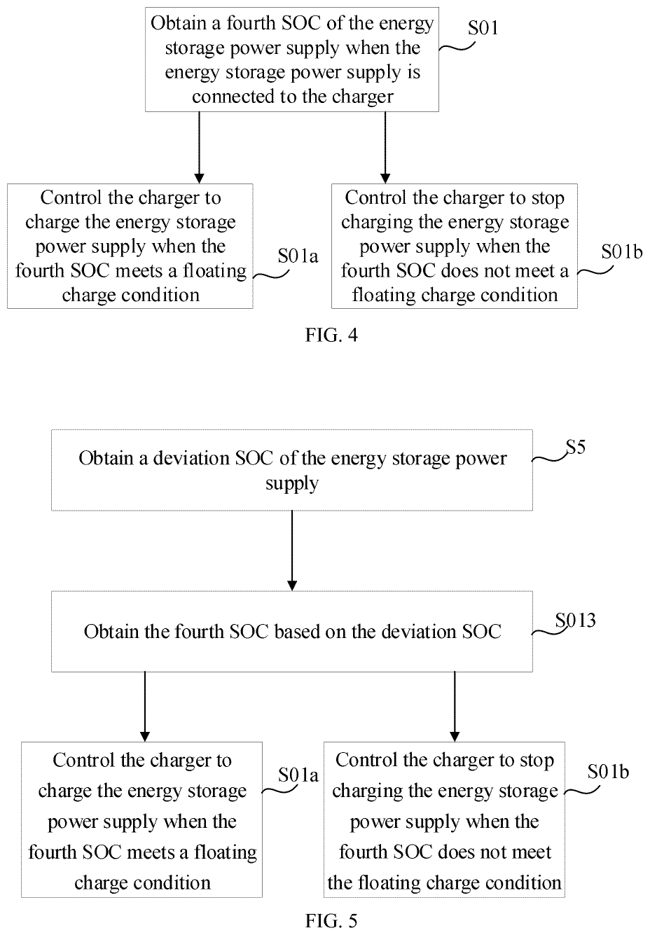

Further, as illustrated in FIG. 4, in some embodiments, the control method includes following steps S01 to S01b.

At step S01, a fourth SOC of the energy storage power supply 1 is obtained when the energy storage power supply 1 is connected to the charger.

At step S01a, the charger is controlled to charge the energy storage power supply when the fourth SOC meets a floating charge condition.

At step S01b, the charger is controlled to stop charging the energy storage power supply 1 when the fourth SOC does not meet a floating charge condition.

In an embodiment, the fourth SOC is the SOC corresponding to the remaining power of the energy storage power supply 1 due to power loss caused by its internal static self-consumption power after the energy storage power supply 1 is connected to the charger and is fully charged (SOC=100%).

Floating charge is a charging method, which is usually used after the battery module 3 of the energy storage power supply 1 is fully charged, and is used to keep the battery module 3 in a fully charged state. Floating charge is charging at a lower voltage and current to compensate for the self-consumption power of the energy storage power supply 1 and maintain the SOC of the battery. However, long-term floating charge not only accelerates life attenuation and affects cycle performance of the battery, but also leads to phenomena such as gas generation in the battery. In severe cases, safety accidents occur, greatly increasing safety risks of battery usage. Therefore, when the fourth SOC meets the floating charge condition, that is, when the power loss of the energy storage power supply 1 reaches a predetermined level, the charger is triggered to charge the energy storage power supply 1, and when the fourth SOC does not meet the floating charge condition, that is, when the power loss of the energy storage power supply 1 does not reach a predetermined level, the charger does not charge the energy storage power supply 1, which can effectively reduce the number of floating charges, avoiding the impact of long-term floating charges to a certain extent.

In addition, when the fourth SOC does not meet the floating charge condition, that is, when the power loss of the energy storage power supply 1 does not reach a predetermined level, there is a power loss of the self-consumption power that does not meet the floating charge condition. A SOC value corresponding to the power loss of the self-consumption power that does not meet the floating charge condition is the deviation SOC, which results in inaccurate first SOC, causing the sudden jump in the first SOC. Therefore, when the energy storage power supply 1 does not meet the floating charging condition to trigger charging and there is the deviation SOC, the first SOC is corrected, that is, the first SOC of the energy storage power supply 1 is obtained based on the load current, the speed factor, and the load duration during the load process of the energy storage power supply 1, effectively reducing the number of floating charges, and improving the accuracy of the first SOC. In this way, the risk of the sudden jump in the first SOC is avoided to a certain extent.

In the above embodiments, the number of floating charges can be effectively reduced, occurrence of negative reactions in the battery under high voltage can be reduced, use consistency, safety, reliability, and service life of the energy storage power supply 1 can be improved. In addition, the accuracy of the first SOC can be improved to avoid the risk of the sudden jump in the first SOC to a certain extent. Therefore, the effective display of the real-time usage state of the energy storage power supply 1 is ensured, guaranteeing the user experience.

Further, in some embodiments, the floating charge condition includes the fourth SOC being less than or equal to a predetermined value.

In an embodiment, when the fourth SOC drops to the predetermined value or falls below the predetermined value, the BMS determines that the energy storage power supply 1 needs to perform floating charge to compensate for self-consumption power of internal components of the energy storage power supply 1, triggering the charger to charge the energy storage power supply 1.

In the above embodiments, when the fourth SOC is less than or equal to the predetermined value, the charger is triggered to charge the energy storage power supply 1. When the fourth SOC is greater than the predetermined value, the charger does not charge the energy storage power supply 1, effectively reducing frequency of triggering floating charge of the energy storage power supply 1.

In an embodiment, when the fourth SOC drops to 95%, the BMS sends a charging instruction to the energy storage power supply 1 to cause the energy storage power supply 1 to turn on a charging switch, allowing the charger to charge the energy storage power supply 1. In addition, the BMS sends a display instruction to the energy storage power supply 1 to cause the user interface to display the SOC of 99%, which can improve the user experience and increase reliability of the energy storage power supply 1.

Further, in some embodiments, the predetermined value is greater than or equal to 90% and less than or equal to 95%.

Since different energy storage power supplies 1 have different specifications, their rated capacities also differ. Setting the predetermined value based on different specifications and capacities of the energy storage power supply 1 can ensure that power demand is met while avoiding excessive floating charge to a certain extent, improving the user experience and effectively extending the service life of the energy storage power supply 1. In an embodiment, when the rated capacity of the energy storage power supply 1 is small, the set value is small. When the rated capacity of the energy storage power supply 1 is large, the set value is large.

In some examples, the set value is equal to 90%, 91%, 92%, 93%, 94%, 95%, or other numerical values greater than or equal to 90% and less than or equal to 95%.

In addition, when the fourth SOC does not meet the floating charge condition and there is the deviation SOC, the set value is greater than or equal to 90%, which can ensure that the deviation SOC remains within a small range, reducing difficulty of correcting the first SOC and improving accuracy and effectiveness of correction.

In the above embodiments, the set value is limited to be greater than or equal to 90% and less than or equal to 95%, which can avoid excessive floating charge to a certain extent and ensure meeting the power demand, and reduce the difficulty of correcting the first SOC and improves the accuracy and effectiveness of the correction.

In an embodiment, the set value is 95%, and the rated capacity C₀ of the energy storage power supply 1 is 10 A·h. When the fourth SOC drops to 97%, the BMS determines that the energy storage power supply 1 does not need to perform the floating charge, and there is a deviation SOC of 3% due to the loss of the self-consumption power. At this time, the charger is unplugged, and the energy storage power supply 1 is loaded, and the load current is 10 A, so the correction duration is 4 minutes. When the energy storage power supply 1 is loaded for 1 minute, the second SOC is 0.75%, the third SOC is 1%, and the first SOC is 98.25%. When the energy storage power supply 1 is loaded for 2 minutes, the second SOC is 1.5%, the third SOC is 2%, and the first SOC is 96.5%. When the energy storage power supply 1 is loaded for 3 minutes, the second SOC is 2.25%, the third SOC is 3%, and the first SOC is 94.75%. When the energy storage power supply 1 is loaded for 4 minutes, the second SOC is 3%, the third SOC is 4%, and the first SOC is 93%. In this case, the correction of the first SOC is completed.

Further, as illustrated in FIG. 5, in some embodiments, step S01 includes following steps S5 and S013.

At step S5, the deviation SOC of the energy storage power supply 1 is obtained.

At step S013, the fourth SOC is obtained based on the deviation SOC.

In an embodiment, when the energy storage power supply 1 remains connected to the charger after being fully charged, the energy storage power supply 1 enters the sleep state. In the sleep state, the electronic components inside the energy storage power supply 1 consume the battery power with a predetermined static self-consumption power level until the fourth SOC meets the floating charge condition, and the energy storage power supply 1 enters a charging state. After being fully charged, the energy storage power supply 1 still maintains the connection with the charger, and enters the sleep state again. This cycle repeats until the charger is unplugged and the energy storage power supply 1 enters the load stage. When the charger is unplugged in a last sleep stage and the energy storage power supply 1 enters the load stage, there may be the deviation SOC. A first SOC accuracy problem caused by the deviation SOC in the last sleep stage needs to be corrected.

The deviation SOC is a ratio of a product of a sleep duration of the last sleep stage and the rated current to the rated capacity C₀ of the energy storage power supply 1, and represents the SOC value corresponding to the battery power consumed by the electronic components inside the energy storage power supply 1 at a predetermined static self-consumption power level in the sleep state.

The speed factor is a ratio of the deviation SOC to the correction duration, and represents the correction speed per unit time during the process of correcting the first SOC.

The fourth SOC is 100% minus the deviation SOC, and represents the SOC value corresponding to the remaining power of the energy storage power supply 1 due to power loss caused by its internal static self-consumption power before meeting the floating charge condition after the energy storage power supply 1 is fully charged. For example, if the deviation SOC is 4%, the fourth SOC is 96%.

In the above embodiments, the fourth SOC may be obtained based on the deviation SOC to determine the floating charge condition. In this way, when the fourth SOC meets the floating charge condition, the charger is triggered to charge the energy storage power supply 1, and when the fourth SOC does not meet the floating charge condition, the charger does not charge the energy storage power supply 1.

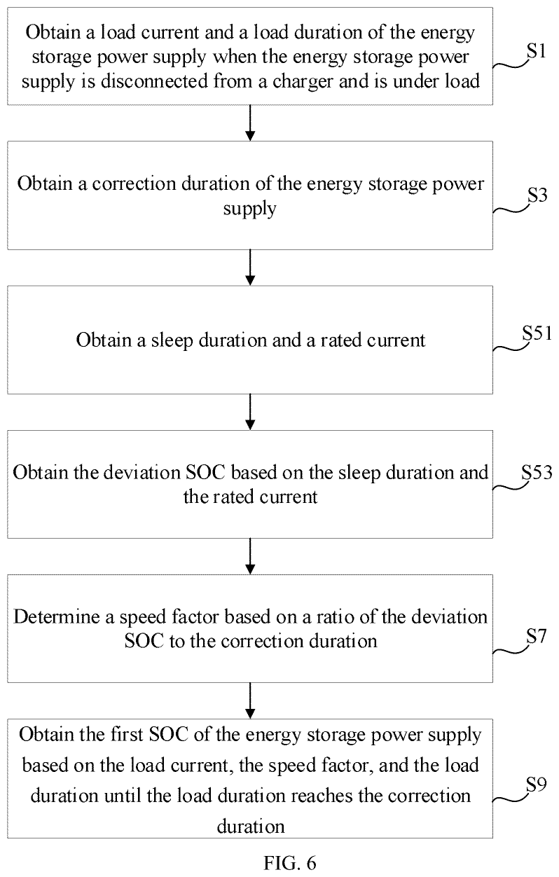

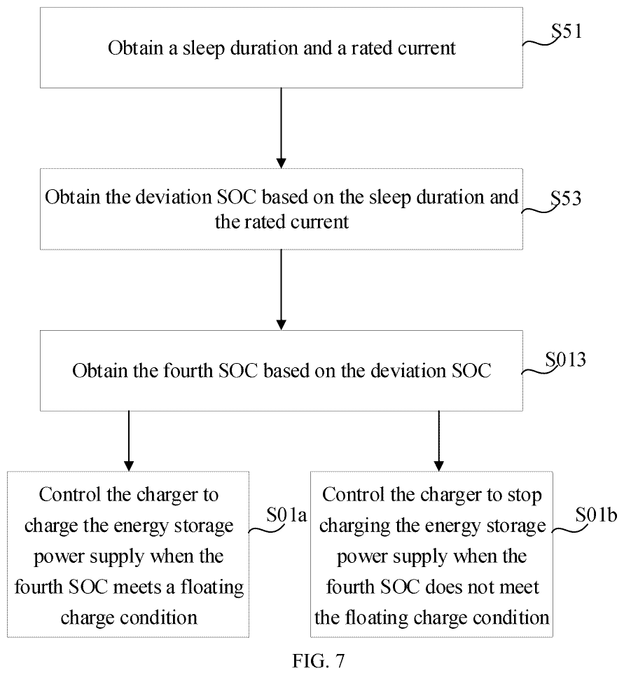

Further, as illustrated in FIG. 6 and FIG. 7, in some embodiments, step S5 includes following steps S51 to S53.

At step S51, a sleep duration and a rated current are obtained.

At step S53, the deviation SOC is obtained based on the sleep duration and the rated current.

In an embodiment, the sleep duration refers to a duration during which the energy storage power supply 1 remains in the sleep state before meeting the floating charge condition. The rated current refers to the discharge current measured in a standardized test when the components inside the energy storage power supply 1 is in the sleep state.

The deviation SOC is the ratio of the product of the sleep duration and the rated current to the rated capacity C₀ of the energy storage power supply 1. For example, if the rated current is 20 mA (milliamperes), the sleep duration is 40 h (hours), and the rated capacity C₀ is 10 A·h, the deviation SOC is 8%.

In the above embodiments, by obtaining the sleep duration and the rated current, and combining them with the rated capacity C₀ of the energy storage power supply 1, the deviation SOC can be accurately calculated, improving effectiveness of correcting the first SOC.

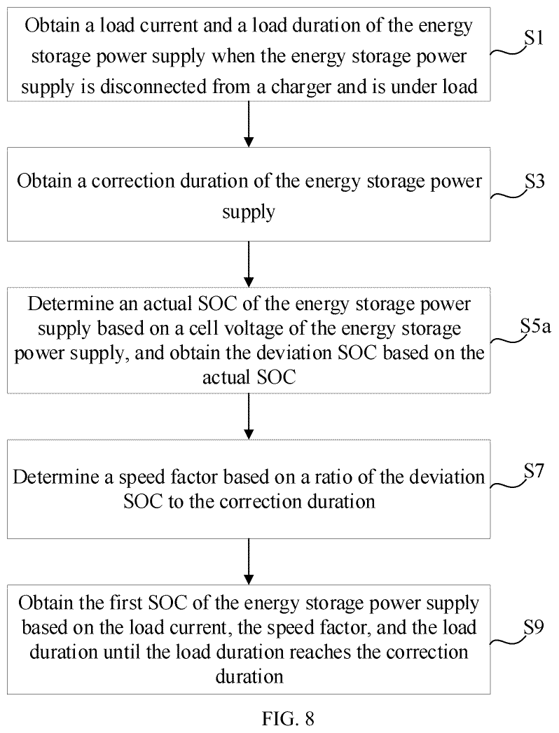

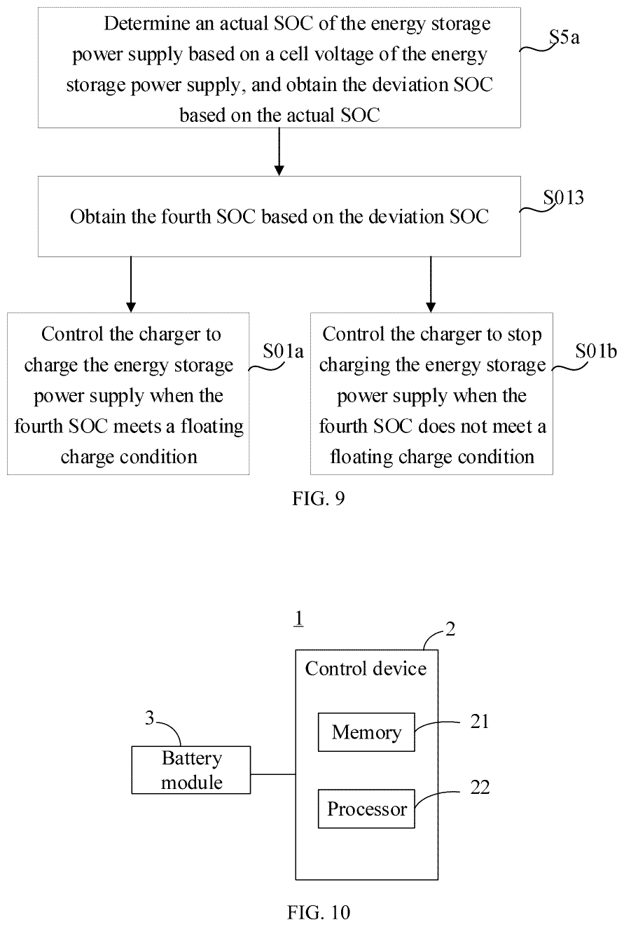

Further, as illustrated in FIG. 8 and FIG. 9, in some embodiments, step 5 includes following step S5a.

At step S5a, an actual SOC of the energy storage power supply 1 is determined based on a cell voltage of the energy storage power supply 1, and the deviation SOC is obtained based on the actual SOC.

In an embodiment, the BMS may monitor the cell voltage of the energy storage power supply 1, obtain a current cell voltage value, and determine the actual SOC of the energy storage power supply 1 based on the collected voltage value by using a predetermined SOC-voltage correspondence (such as through a look-up table or calculation). The deviation SOC may be determined based on the actual SOC. For example, if the SOC value corresponding to the cell voltage of the energy storage power supply 1 is detected to be 97%, the deviation SOC is the difference between 100% and 97%, that is, the deviation SOC is 3%.

In the above embodiments, the deviation SOC may be accurately calculated by obtaining the cell voltage of the energy storage power supply 1, improving the effectiveness of correcting the first SOC.

As illustrated in FIG. 10, a control device 2 according to an embodiment of the present disclosure includes a processor 22 and a memory 21 having a computer program stored thereon. The computer program, when executed by the processor 22, implements steps of the control method according to any one of the above embodiments.

As illustrated in FIG. 10, an energy storage power supply 1 according to an embodiment of the present disclosure includes the control device 2 according to the above embodiment. In an embodiment, the energy storage power supply 1 includes a battery module 3, and the control device 2 is electrically connected to the battery module 3. The control device 2 may be disposed in the BMS, or may be connected to the BMS by wired or wireless communication.

A computer-readable storage medium having a computer program stored thereon is provided according to an embodiment of the present disclosure. The computer program, when executed by a processor 22, implements steps of the control method according to any one of the above embodiments.

In some embodiments, the computer program is executed by the processor 22, to implement the control method including following steps S1 to S9.

At step S1, a load current and a load duration of the energy storage power supply 1 are obtained when the energy storage power supply 1 is disconnected from a charger and is under load.

At step S3, a correction duration of the energy storage power supply 1 is obtained. At step S5, a deviation SOC of the energy storage power supply 1 is obtained.

At step S7, a speed factor is determined based on a ratio of the deviation SOC to the correction duration.

At step S9, a first SOC of the energy storage power supply 1 is obtained based on the load current, the speed factor, and the load duration until the load duration reaches the correction duration.

In the description of this specification, descriptions with reference to the terms “an embodiment”, “some embodiments”, “illustrative embodiments”, “examples”, “specific examples” “some examples” etc., mean that specific features, structure, materials, or characteristics described in conjunction with the embodiment or example are included in at least one embodiment or example of the present disclosure. In this specification, the schematic representations of the above terms do not necessarily refer to the same embodiment or example. Moreover, the described specific features, structures, materials or characteristics may be combined in any one or more embodiments or examples in a suitable manner.

Any process or method described in a flowchart or described herein in other ways may be understood to include one or more modules, segments, or portions of codes of executable actions for achieving specific logical functions or steps in the process. The scope of a preferred embodiment of the present disclosure includes other implementations. A function may be performed not in a sequence shown or discussed, including a substantially simultaneous manner or a reverse sequence based on the function involved, which should be understood by those skilled in the art to which the embodiments of the present disclosure belong.

Although embodiments of the present disclosure have been illustrated and described above, it should be understood that the above embodiments are merely exemplary, and cannot be construed to limit the present disclosure. For those skilled in the art, changes, combinations, alternatives, and modifications can be made to the embodiments without departing from the scope of the present disclosure.

What is claimed is:

1. A control method, applied to an energy storage power supply that displays a first state of charge, the method comprising:
obtaining a load current and a load duration of the energy storage power supply when the energy storage power supply is disconnected from a charger and is under load;
obtaining a correction duration of the energy storage power supply;
obtaining a deviation state of charge of the energy storage power supply;
determining a speed factor based on a ratio of the deviation state of charge to the correction duration; and
obtaining the first state of charge of the energy storage power supply based on the load current, the speed factor, and the load duration until the load duration reaches the correction duration.

2. The control method according to claim 1, wherein said obtaining the correction duration of the energy storage power supply comprises:
obtaining the correction duration of the energy storage power supply based on the load current, the correction duration being negatively correlated with the load current.

3. The control method according to claim 2, wherein there is a predetermined mapping relationship between the correction duration and the load current.

4. The control method according to claim 3, wherein the predetermined mapping relationship is related to a rated capacity of the energy storage power supply.

5. The control method according to claim 4, wherein the predetermined mapping relationship comprises at least one of the following:
the correction duration is 8 minutes when the load current is less than 0.5 times the rated capacity;
the correction duration is 4 minutes when the load current is greater than or equal to 0.5 times the rated capacity and less than or equal to 1 time the rated capacity; and
the correction duration is 2 minutes when the load current is greater than 1 time the rated capacity.

6. The control method according to claim 1, wherein said obtaining the first state of charge of the energy storage power supply based on the load current, the speed factor, and the load duration comprises:
obtaining a second state of charge based on the speed factor and the load duration;
obtaining a third state of charge based on the load current and the load duration; and
obtaining the first state of charge based on the second state of charge and the third state of charge.

7. The control method according to claim 6, wherein the speed factor is a ratio of the deviation state of charge to the correction duration.

8. The control method according to claim 6, wherein:
the second state of charge is a product of the load duration and the speed factor, and/or
the third state of charge is a ratio of a product of the load duration and the load current to a rated capacity of the energy storage power supply.

9. The control method according to claim 1, further comprising:
obtaining a fourth state of charge of the energy storage power supply when the energy storage power supply is connected to the charger; and
controlling the charger to charge the energy storage power supply when the fourth state of charge meets a floating charge condition.

10. The control method according to claim 1, further comprising:
obtaining a fourth state of charge of the energy storage power supply when the energy storage power supply is connected to the charger; and
controlling the charger to stop charging the energy storage power supply when the fourth state of charge does not meet a floating charge condition.

11. The control method according to claim 9, wherein the floating charge condition comprises the fourth state of charge being less than or equal to a predetermined value.

12. The control method according to claim 11, wherein the predetermined value is greater than or equal to 90% and less than or equal to 95%.

13. The control method according to claim 9, wherein said obtaining the fourth state of charge of the energy storage power supply when the energy storage power supply is connected to the charger comprises:
obtaining the deviation state of charge of the energy storage power supply; and
obtaining the fourth state of charge based on the deviation state of charge.

14. The control method according to claim 1, wherein said obtaining the deviation state of charge of the energy storage power supply comprises:
obtaining a sleep duration and a rated current of the energy storage power supply; and
obtaining the deviation state of charge based on the sleep duration and the rated current.

15. The control method according to claim 14, wherein the deviation state of charge is a ratio of a product of the sleep duration and the rated current to the rated capacity of the energy storage power supply.

16. The control method according to claim 1, wherein said obtaining the deviation state of charge of the energy storage power supply comprises:
determining an actual state of charge of the energy storage power supply based on a cell voltage of the energy storage power supply, and obtaining the deviation state of charge based on the actual state of charge.

17. The control method according to claim 16, wherein the actual state of charge of the energy storage power supply is determined based on the cell voltage of the energy storage power supply and a correspondence between a predetermined state of charge and voltage.

18. A control device for an energy storage power supply, the control device comprising:
a processor; and
a memory having a computer program stored thereon, the computer program, when executed by the processor, implementing steps of a control method applied to the energy storage power supply, the energy storage power supply displaying a first state of charge, and the control method comprising:
obtaining a load current and a load duration of the energy storage power supply when the energy storage power supply is disconnected from a charger and is under load;
obtaining a correction duration of the energy storage power supply;
obtaining a deviation state of charge of the energy storage power supply;
determining a speed factor based on a ratio of the deviation state of charge to the correction duration; and
obtaining the first state of charge of the energy storage power supply based on the load current, the speed factor, and the load duration until the load duration reaches the correction duration.

19. An energy storage power supply, comprising the control device according to claim 18.

20. A non-transitory computer-readable storage medium, having a computer program stored thereon, wherein the computer program, when executed by a processor, implements steps of a control method applied to an energy storage power supply, the energy storage power supply displaying a first state of charge, and the control method comprising:
obtaining a load current and a load duration of the energy storage power supply when the energy storage power supply is disconnected from a charger and is under load;
obtaining a correction duration of the energy storage power supply;
obtaining a deviation state of charge of the energy storage power supply;
determining a speed factor based on a ratio of the deviation state of charge to the correction duration; and
obtaining the first state of charge of the energy storage power supply based on the load current, the speed factor, and the load duration until the load duration reaches the correction duration.
